(19) United States
(12) Patent Application Publication
(10) Pub. No.: US 2026/0334377 A1
(43) Pub. Date: Oct. 29, 2026

(54) METHODS, SYSTEMS, AND APPARATUSES FOR PRODUCING, GENERATING AND UTILIZING POWER AND ENERGY

(71) Applicants: Yttrium Kai Saiyan, Tyler, TX (US); Amethyst Kai Saiyan, Tyler, TX (US)

(72) Inventors: Yttrium Kai Saiyan, Tyler, TX (US); Amethyst Kai Saiyan, Tyler, TX (US)

(21) Appl. No.: 19/641,171

(22) Filed: Apr. 7, 2026

Related U.S. Application Data
(63) Continuation of application No. 17/686,526, filed on Mar. 4, 2022.
(60) Provisional application No. 63/157,048, filed on Mar. 5, 2021.

(51) Int. Cl. A01G 7/04

(52) U.S. Cl. CPC A01G 7/045

(57) ABSTRACT

The present disclosure relates to a method for producing a crystal. In non-limiting embodiments, the method comprises heating a first compound comprising Al₂O₃ to form a molten Al₂O₃; introducing a second compound comprising TiO₂ in the molten Al₂O₃ under a partial pressure of a non-reactive gas; and forming the crystal comprising Ti³⁺:Al₂O₃.

### PRIORITY

This application claims the benefit under 35 U.S.C. § 120 as a continuation of application Ser. No. 17/686,526, filed Mar. 4, 2022, which claims the benefit under 35 U.S.C. § 119(e) of provisional Application No. 63/157,048, filed Mar. 5, 2021, the entire contents of which are hereby incorporated by reference as if fully set forth herein.

Aspects of the invention are disclosed in the following description and related drawings directed to specific embodiments of the invention. Those skilled in the art will recognize that alternate embodiments may be devised without departing from the spirit or the scope of the claims. Additionally, well-known elements of exemplary embodiments of the invention will not be described in detail or will be omitted so as not to obscure the relevant details of the invention. Further, to facilitate an understanding of the description discussion of several terms used herein follows.

As used herein, the word “exemplary” means “serving as an example, instance or illustration.” The embodiments described herein are not limiting, but rather are exemplary only. It should be understood that the described embodiment are not necessarily to be construed as preferred or advantageous over other embodiments. Moreover, the terms “embodiments of the invention”, “embodiments” or “invention” do not require that all embodiments of the invention include the discussed feature, advantage or mode of operation.

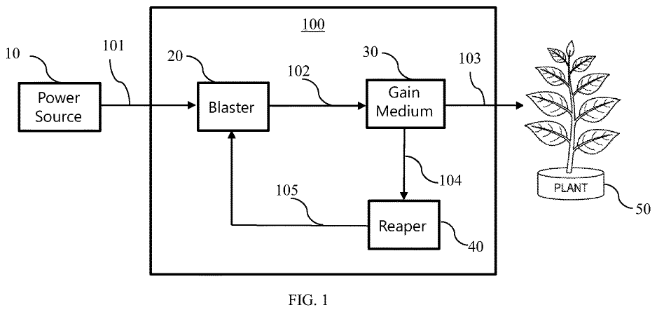

FIG. 1 illustrates a schematic diagram of an exemplary solid-state device for producing and utilizing energy for botanical growth.

In an exemplary embodiment, a Quantum Botanix may be provided.

This solid-state exemplary embodiment may include a gain medium, a reaper, a combination of coatings, and a blaster. When assembled, the device may emit light at a particular wavelength and frequency that yields optimal plant growth and maturation. With this increase in growth efficiency, this device may be used in a variety of botanical settings to decrease energy usage, cut down on production costs, and increase overall plant production.

### Structure

The materials that make up this exemplary embodiment may be combined with a circuitry component that relays a message to pulse the blaster at a specific frequency. As light is pulsed within the exemplary embodiment, it may then be amplified by the gain medium. The gain medium may emit this amplified photonic energy within a specific bandgap of electromagnetic energy. This energy is then effectively distributed onto the photosynthetic portions of the associated plants exposed to the solid-state exemplary embodiment.

If using a reaper, a reaper may be adhered to a specific face of the reactor where it may absorb and convert photonic energy emitted by the reactor. The reaper may then convert this photonic energy into usable electrical energy via the photovoltaic effect that may take place within the photosensitive portions of the material. This electrical energy may be used to supply current to the blaster via the associated circuitry. This may allow for the exemplary embodiment to become self-sustaining.

Initially, as illustrated in FIG. 1, an external power source 10 may be necessary to jump-start the exemplary embodiment 100. For instance, a photovoltaic device, or any other device that emits electric current 101 may be needed to initially power the blaster 20. Once jump started, the exemplary embodiment 100 may continue to emanate photonic energy for plant growth and maturation, while simultaneously supplementing its own power requirements.

If a reaper 40 is not used, the solid-state exemplary embodiment may rely on an external power source 10 to supply current 101 to the blasters 20 within the device 100.

Plants 50 may also be configured in such a way that all photosensitive areas are most effectively exposed to the photonic energy 103 emanated by the solid-state exemplary embodiment.

The order and orientation of these materials that make up this exemplary embodiment may be as follows, or it may be any other combination of these materials that allows for the most seamless amplification and distribution of photonic energy within this solid-state exemplary embodiment.

Blaster 20: A light source that may emit photonic energy at a specific wavelength that is most readily absorbed by the gain medium 30 within the solid-state device 100. The blaster 20 may emit light in the form of constant wave or at a specific timed pulse determined by the circuitry associated with this exemplary embodiment.

The materials that make up the blaster 20 may include a photodiode, that may be made from elements from groups III and V in the periodic table. These elements may include, but are not limited to GaAs, InGaN, GaP, or any other type of photo-illuminating material that emits wavelengths of light that are within the absorption spectrum of the gain medium 30.

The wavelength of light emitted by the blaster 20 is also determined to the peak absorption wavelength of the plants 50 exposed to the solid-state exemplary embodiment 100. Meaning the blaster 20 and gain medium 30 may each be tuned to consequently emit a bandgap of electromagnetic energy that is most readily absorbed by the photosynthetic portions of the associated plants 50 exposed to this solid-state exemplary embodiment 100.

The frequency of which the light 102 is emitted by the blaster 20 is contingent on the frequency of light at which the associated plants 50 absorb light most efficiently. This may allow for optimal growth and maturation of the plants 50 exposed to the solid-sate exemplary embodiment 100.

This frequency may also be determined by the gain medium 30 as well. The amplification potential of the gain medium 30 may be contingent on the frequency at which it absorbs photonic energy. Blasters 20 may be tuned to pulse at this specific frequency to yield the largest gain potential within the crystalline lattice structure of the exemplary embodiment.

The blaster 20 may also be oriented in such a way that it is fixed to the most photoreactive portion of the gain medium 30. This may allow for optimal transmission of photonic energy 102 from the blaster 20 into the crystalline lattice structure of the gain medium 30 for absorption and amplification.

The photoreactive portion, or also referred to as the absorption face, of the gain medium 30 may be polished at a specific incident angle to allow for seamless transmission of light 102 from the blaster 20 to enter the crystalline lattice structure of the material. This may decrease reflection losses and may increase overall efficiency of the solid-state exemplary embodiment as photonic energy emitted by the blaster 20 is readily absorbed by the gain medium 30.

Gain medium 30: A certain crystalline lattice structure, which may also referred to as a power core, that may allow for the even distribution and amplification of photonic energy within this solid-state exemplary embodiment. The blaster 20 may emit a certain wavelength or bandgap of light 102 at a specific timed frequency, at constant wave, or with any other delivery method that allows for the crystalline lattice structure of the gain medium 30 to reach optimal saturation power. Once the gain medium 30 has become saturated with photonic energy, stimulated emission may take place within the structure. This allows for the amplification and even distribution of photonic energy within the solid-state exemplary embodiment. The power core may also be configured in such a way where it emits photonic energy to all photosynthetic portions of the plants at which it is targeting.

Materials that make up the power core may include Ti³⁺: Al₂O₃, Nd: YAG, Ce: YAG, Er: YAG, Nd: YVO₄, or any other type of crystalline lattice structure that allows for photonic energy to emanate from the gain medium 30 and enter the photosynthetic portions of the associated plants 50.

When choosing a material, it may be necessary to look at the chemical compound's peak absorption and emission wavelengths. If its peak emission wavelength matches the peak absorption wavelength of the plants at which it is targeting, that material may be chosen. Blasters may either be tuned to emit a specific bandgap of photonic energy that matches the peak absorption spectrum of the crystalline lattice structure. By taking these spectrums into consideration, optimal saturation power and photonic emanation may be achieved within the gain medium, as well as maximum growth and maturation within the associated plants.

The gain medium may become saturated with photonic energy via the blasters through the process of q-switching, gain switching, mode-locking, or any other type of pulsation of photonic energy that allows for the crystalline lattice structure to reach its gain potential as quickly and efficiently as possible.

Reaper 40: The reaper may include a photoelectric material and positioned to where it may harness the photonic energy 104 emitted by the gain medium 30, while simultaneously allowing for a portion of the emanated photonic energy 103 to exit the gain medium and enter the photosynthetic portions of the associated plants 50. As the gain medium evenly distributes the pulsed or constant waves of photonic energy, the reaper 40 may collect this photonic energy 104 and simultaneously convert it into useable electrical energy 105. The reaper 40 may also be connected to the circuitry associated with this exemplary embodiment. As the reaper 40 collects photonic 104 emitted by the gain medium 30, the energy may be used to power the blaster 20 within the solid-state exemplary embodiment 100.

The reaper 40 may include a variety of different crystalline photoelectric materials. These include GaAs, InGaN, mono or polycrystalline silicon, CdTe, or any other type of chemical combination that may readily convert photonic energy into electrical energy.

Materials chosen may be dependent upon the peak emission wavelength of the gain medium, as well as the peak absorption spectrum of the chemical compounds chosen to make up photoelectric material. If these spectrum's match, it may allow for increases in transmission of photonic energy between the gain medium and the photoelectric material. Limiting the amount of reflection losses may allow for significant increases in output potential.

The crystalline lattice structure of the reaper may also be index matched and positioned so that its orientation matches the crystalline orientation of the gain medium. This may decrease the amount of reflection losses within the system and allow for seamless transition of photonic energy throughout the solid-state exemplary embodiment.

The reaper may also include circuitry that connect the newly converted electrical energy to the blasters in the solid-state exemplary embodiment. This may allow for the solid-state device to supplement its own power requirements, thereby improving overall energy efficiency.

Coatings: Another component of this solid-state exemplary embodiment may include the use of specialized coatings that aid in the seamless transmission of light throughout the device. These coatings may also be used to either transmit or reflect specific wavelengths of light depending on their structure and location within the exemplary embodiment.

Highly reflective coating: This type of coating may be used on one, multiple, or all faces of the gain medium, blaster, reaper and/or any other material that transmits light within the exemplary embodiment. This coating may include two materials: one with a high index of refraction and one with a low index of refraction. Zinc sulfide, titanium dioxide, or any other chemical combination that has a high index of refraction may be used in combination with magnesium fluoride, silicon dioxide, or any other chemical combination with a low index of refraction. This coating may be tuned to reflect light at specific wavelengths and tailored towards the pathway of light through the solid-state exemplary embodiment. Tuning of the coating may be accomplished through determining a specific ratio between the two indices. These differences in refractive indices are what may allow for constructive interference that maximizes reflection of some wavelengths, while minimizing reflection in others.

The purpose of this coating in this solid-state exemplary embodiment may be to trap wavelengths of light that are within the peak absorption bandgap for the material that makes up the gain medium. By selectively trapping this spectrum of light, the system may amplify a larger quantity of photonic energy thereby increasing the overall optical power output potential of the device.

When not using a reaper, this coating may be applied to the back face of the gain medium. This may allow for emanated photonic energy to become focused on the photosynthetic portions of the associated plants rather than being lost through the back face. In this case, the coating may be tuned to reflect wavelengths within the gain medium's peak emission spectrum.

If using a reaper, this coating may still be utilized on any other face of the gain medium, while not interfering with the blasters or the emission face. It may be necessary to use these coatings on the side faces to focus as much photonic energy out through the emission face where it may exit the gain medium and enter the photosynthetic portions of the associated plants.

This coating may also be placed on the back side of the reapers as well. The purpose of this placement would be to decrease the overall loss of photonic energy that may exit the photoelectric material, before having the chance to become absorbed. This increases the overall amount of available photonic energy that may be harnessed and converted into useable electrical energy within the exemplary embodiment.

Antireflective Coating: This type of coating may be used on one, multiple, or all faces of the gain medium, blaster, reaper and/or any other material that transmits light within the exemplary embodiment. The coating includes different layers of materials with varying refractive indices. Each layer in the coating stack combines with the previous layer to introduce destructive waves that are out of phase with the light waves that encounter the coating. This is accomplished through creating a reflection from the second surface that may be half the wavelength out of the phase from the initial reflection. This may create two reflections which cancel each other out allowing for most light to transmit through to the power core. Like the highly reflective coating, this coating may be tuned to allow for certain wavelengths of light within a specific bandgap to pass through with minimal reflection, while interfering with others. This selection of wavelengths may be dependent upon the location of the AR coating within the exemplary embodiment, as well as what wavelengths of light the coating may encounter.

The purpose of this coating would be to decrease the amount of photonic energy that is lost from reflection as it travels from one medium to another. For instance, within this solid-state embodiment, there may be significant reflection losses when photonic energy exits the gain medium and enters the absorption face of the reaper. If an AR coating were to be placed on either the exit face of the power core, or on the absorption face of the reaper, total reflection losses within the device may be substantially minimized. Blasters may also require an AR coating to decrease the amount of reflection losses as they transmit photonic energy into the primary absorption face(s) of the gain medium.

Index matching coating: One of the many forms of an antireflective coatings may also be deposited onto the absorption face of the reaper, or the emission face of the blaster, and may be used has a method to decrease the total amount of reflection losses within this solid-state exemplary embodiment. This index matching coating may be accomplished through the deposition of different chemical compositions with varying refractive indices. The selection of chemical compounds may be dependent upon the refractive indices of the reaper, gain medium, and/or blaster. There may be a gradient of varying refractive indices each lying between the refractive indices of the gain medium and the reaper, or the blaster and the gain medium. There may be one or multiple layers of this coating within this solid-state exemplary embodiment.

The purpose of this index matching coating may be to decrease the amount of photonic energy lost as it transitions from the excitation face of the power core onto the absorption face of the reaper. This increases the overall transmission of photonic energy into the reaper stimulating the materials ability to undergo the photoelectric effect producing usable electrical energy.

When deposited between the absorption face of the gain medium and the emission face of the blaster, the purpose of the index matching coating may be to mitigate reflection losses as the photonic energy exits the blaster and enters the gain medium.

Dichromatic coating: This type of coating may be used on one, multiple, or all faces of the gain medium, blaster, reaper and/or any other material that transmits light within the exemplary embodiment. This dichromatic coating, also referred to as a dichroic filter, may be effective by producing destructive interference with specific wavelengths in the electromagnetic spectrum. Destructive interference is accomplished through using altering refractive indices to produce phased reflections, thereby allowing certain wavelengths of light to transmit while interfering with other wavelengths. Therefore, during destructive interference, light of a particular wavelength is unable to permeate the coating and is instead reflected off. Light of a differing wavelength may then transmit through the coating depending upon the refractive indices of the chemical compounds used to construct the coating. These coatings may be engineered to target wavelengths within the peak absorption and peak emission bandgaps of the gain medium, reaper, blaster, or any other material that is used to transmit photonic energy within the solid-state exemplary embodiment.

Bandpass Filter: Multiple different types of dichromatic coatings may be used on one, multiple, or all faces on the power core, blaster, reaper and/or any other material that transmits light within the exemplary embodiment This is a type of dichromatic coating that differs in the sense that it allows for more specific tunability of the coating when relating to the selection of wavelengths it will reflect or transmit. A bandpass filter may reflect and transmit multiple different wavelengths at varying spectrums. The angle at which light penetrates or reflects from this filter is dependent upon the angle at which the coating is oriented. Therefore, its effectiveness may increase if the angle of incident were to match the incident angle of which the filter is receiving light.

The purpose of this filter is its ability to transmit and reflect light at varying spectrums. This allows for the coating to operate more specifically to the performance metrics dictated by the peak absorption and emission wavelengths of the gain medium, blaster, reaper, and/or any other material within the exemplary embodiment that is involved in the transmission of light.

Example of How it Works:

The solid-state exemplary embodiment 100 may be configured in a way that allows for the finely tuned emission of photonic energy 103 at a specific bandgap and frequency that is most readily absorbed by the photosynthetic portions of the associated plants 50. This may be accomplished through the unique manipulation and harnessing of photonic energy that takes place within the photosensitive materials of the exemplary embodiment. Each structure may be oriented in such a way that allows for the seamless transmission, collection, and emission of specific wavelengths of light at extremely high efficiencies.

As the blaster 20 emits light 102 at either constant wave, or at a timed frequency, the gain medium 30 readily absorbs this photonic energy 102. Stimulated emission may also take place within the crystalline lattice structure allowing for a larger amount of photonic energy 103 and 104 to exit the material, in comparison to the amount of energy emitted by the blaster 20.

The emanated photonic energy 104 from the gain medium 30 may also be absorbed by the reaper 40. The reaper 40 may convert this photonic energy 104 into usable electrical energy 105 that may be used to power the blaster 20 within the solid-state exemplary embodiment 100.

The emanated photonic energy 103 from the gain medium 30 may also be focused on the photosynthetic portions of the associated plants 50. This energy may be allowed to seamlessly exit the emission face of the gain medium 30 with minimal reflection losses. This may be accomplished using optical coatings that aid in transmission within the gain medium 30.

Every plant 50 has its own intrinsic absorption spectrum at which it absorbs photonic energy at high efficiencies. The frequency of light may also determine how readily the photosynthetic portions are able to absorb photonic energy as well. Therefore, the solid-state exemplary embodiment may be tuned to emit photonic energy 103 at this optimal frequency and wavelength. By taking these variables into consideration, the solid-state exemplary embodiment 100 may allow for plants 50 to grow and mature at high efficiencies. This may be because the photosynthetic portions of each plant 50 are able to absorb photonic energy and convert it into usable energy for growth and maturation at high efficiencies.

Example of How it is Made:

This exemplary embodiment includes a variety of materials that may include a variety of different molecular and chemical compounds. Each molecular and chemical compound is intrinsic to the solid-state device in the sense that these chemical bonds are what allow for the emanation of photonic energy, its efficient conversion into usable electrical energy, and/or its distribution to the photosynthetic portions of the associated plants.

Blaster: The blaster is made of a semiconductor compound that emits a specific wavelength of photonic energy when an electric current passes through the material.

Semiconductor materials: Blasters may include a compound of semiconductor materials that include elements from groups III and V on the periodic table. Some compounds may include, but are not limited to InGaN, AlGaInP, AlGaAs, and GaP.

These semiconductor materials may be deposited as very thin layers. One layer may have an excess number of electrons, while the subsequent layer may have a deficient number of electrons. These are known as electron holes. The difference allows for electrons to flow and fill the holes in the deficient layer, emitting photonic energy as they become displaced and enter a different energy level.

The layers of semiconductors may also be manufactured with impurities that increase the rate at which the electrons flow from each layer. This is also known as doping. During the manufacturing process, zinc, nitrogen, silicon, germanium, tellurium, or any other element that increases the rate that the blaster may emanate photonic energy. The doping allows for the semiconductor material to conduct electricity through creating either a deficit or excess in electrons.

The blaster may be tuned to emit a specific bandgap of light. This bandgap may be wide or narrow depending upon semiconductor materials used. Each chemical compound used in the semiconductor has a different emission bandgap. This emission bandgap may be tuned to match the absorption spectrum of the chemical compounds used to make up the gain medium. By matching these bandgaps, photonic energy can transition from the blaster into the gain medium at high efficiencies with minimal reflection losses.

The selection of chemical compounds that make up the semiconductor material may be dependent upon the desired emission wavelength for the blaster. Once a bandgap is selected, a chemical compound that emanates this spectrum may be selected.

Growth Process: The crystalline semiconductor material may be grown in a high temperature, high pressure chamber. The main semiconductor materials, such as gallium, arsenic, and phosphorus may be subject to high heat and high pressure causing the components to liquefy and mix together. A solution, such as boron oxide, may then be deposited over the surface preventing the components from the mixture to escape as a gas, causing the solution to stick together. Once the solution has been mixed, a long rod may then be dipped into the solution and slowly removed creating a cylindrical crystal boule of GaAs, GaP, GaAsP, or any other crystalline semiconductor compound.

Once the boule has been grown, it may be sliced into extremely thin wafers. The wafers may be polished to a clean and clear surface finish. Polishing may be necessary when layering the semiconductor materials so that they may effectively electrons from one wafer to the next. Polishing may also allow for the blaster to emit a much cleaner beam profile as imperfections are mitigated.

Once polished, the wafers may then be ultrasonic cleaned with various solvents. The cleaning prevents impurities from creating inefficiencies in the blaster and may yield a cleaner beam profile.

Once the first layer is created, additional layers may be grown on the clean, polished surface. These additional semiconductor layers may have the same orientation as the subsequent layer below and may be epitaxially deposited on the wafer as it is exposed to reservoirs of molten GaAsP. These reservoirs may also include dopants, such as zinc, nitrogen, silicon, germanium, tellurium, or any other element that increases the rate that the blaster may emanate photonic energy. The wafer may be set on a graphite slide as the molten liquid is deposited over the surface.

Additional layers may be added to alter the emission wavelength as well.

Additional dopants may be added as well to alter the emission wavelength. Dopants may also be added to increase overall efficiency as well.

Additional doping: If additional doping is needed, the wafer is placed in a high temperature, high pressure furnace tube, where it is exposed to dopants in their gaseous state. Nitrogen, zinc ammonium, or any other chemical compound that increases overall efficiency may be used as a dopant.

To carry an electric current, the blaster may be configured with wires that may effectively carry an electric current. Some elements that may be used include gold, silver, copper, or any other highly conductive element or chemical compound. These conductive wires may also form chemical bonds with the semiconductor material, such as the gallium, allowing for efficient transfer of electricity.

Packaging: Blasters may be packaged individually or in series, depending upon which orientation allows for the greatest amount of photonic energy to emanate within the gain medium.

Blasters may also be assembled in glass or plastic casings as well. The casing may include optical coatings or may be made of a specific material that increases beam and transmission quality.

Coating: The blaster may also require an optical coating deposited over its top layer. This may be necessary to properly index match the top surface of the blaster to the gain medium, or to whatever medium the blaster is emitting photonic energy into. By matching the index of refraction, photonic energy can readily exit the blaster and enter the gain medium at high efficiencies with minimal reflection losses.

### Gain Medium

Crystalline-Lattice structure: This molecular compound may have a specific orientation and lattice structure that may have an associated gain potential. When the material is exposed to light in its peak absorption bandgap at a specific frequency, stimulated emission may occur within the power core, emanating newly generated photonic energy in the form of the medium's peak emission spectrum.

Possible crystals: There are many crystals that may have gain potentials that embody the characteristics listed above. Some of these crystals may include Ti³⁺: Al₂O₃, Nd: YAG, Cs: YAG, or any other crystal/chemical compound that has an intrinsic gain potential.

The gain medium may be cut, fabricated, polished, and coated before it is able to effectively provide a gain potential.

The gain medium may be spherical, rectangular, triangular, or any other type of crystalline configuration that allows for the harnessing and amplification of photonic energy. The shape of the gain medium may also be dependent upon which shape allows for the most photonic energy to exit the gain medium and enter the photosynthetic portions of the associated plants.

The gain medium may also be polished at a specific incident angle that may allow for the seamless transmission of light with minimal reflection losses. This angle may be a Brewster Angle, or any other type of configuration that decreases reflection and allows for seamless transmission of light into the gain medium. This polished side may be referred to the absorption face of the gain medium.

Blasters may be fixed to the absorption face of the gain medium. They may be fabricated, oriented, and coated in such a way to decrease reflection losses, while simultaneously allowing for the greatest amount of photonic energy to exit the blaster and enter the crystalline lattice structure of the gain medium as possible. This may increase the overall efficiency of the exemplary embodiment.

### Photoelectric Material

This is the site where the photoelectric effect takes place within the solid-state device. The material that is used here may be highly excitable by photonic energy. The material may also be specifically excited by specific wavelengths of light. For instance, this material may be selectively excited by the peak emission bandgap of the gain medium associated with this solid-state device. This allows for the newly created photonic energy from the gain medium to excite the electrons within the photoelectric material generating a useable electric current.

Chemical composition: This material may include a variety of different chemical or molecular compositions. Of which, specific chemical or molecular compounds such as GaAs, InGaN, GaInP, polycrystalline silicon, SiN, CdTe, or any other chemical compound that can partake in the photoelectric effect. Another important characteristic of the material may be for its peak absorption bandgap to match the associated gain medium's peak emission bandgap.

Exemplary Assembly: This material may be coated with an antireflective coating, dichromatic coating, or any other coating that decreases the amount of photonic energy that is lost due to reflection. This prevents the loss of photonic energy that is necessary to stimulate the movement of electrons within the material. By having this coating, the necessary light is directed and evenly distributed across the faces of the photoelectric material. This increases the instances of freely moving electrons allowing the conversion of photonic to electrical energy to become increasingly more efficient. There may also be a highly reflective mirror that lies on the back of the solid-state device. This allows for light not initially absorbed by the gain medium to be directed back into the crystal to initiate stimulated emission. The reflective coating may also reflect the newly generated photonic energy so that it exits emission face and enters the photosynthetic portions of the associated plants.

Coatings may be deposited using electron beam physical vapor deposition, ion assisted deposition, ion beam sputtering, or any other type of coating deposition process that allows for the effective distribution of coatings onto the faces of the photoelectric material.

The coatings may be evaporated evenly over the faces of the photoelectric material. This allows for the coating to evenly act on the entire face of the material increasing the amount of available surface area for the photovoltaic effect to continuously occur. The photoelectric material is then effectively adhered to the back of the gain medium. This may be done using a resin whose index of refraction matches the gain medium allowing for light to seamlessly pass through onto the face of the photoelectric material.

As light enters the gain medium, it may allow for stimulated emission to occur within the gain medium. Newly generated energy may exit the medium in the form of its peak emission bandgap. This light may then become readily absorbed by the photoelectric material. Once the photonic energy undergoes the photoelectric effect within this material, electrical energy may be harnessed and implemented into a variety of use cases.

### Coatings

Dichromatic Coating: This may include a variety of different materials. The chemical or molecular compound is selectively permeable to light that is within the peak emission wavelengths of the sun. This wavelength consequently may also be within the bandgap of the solid-state device's gain medium's peak absorption.

This coating is applied to the polished surface of the gain medium. There are multiple ways to adhere this coating to the exemplary embodiment. One of which includes evaporating the chemical or molecular compound evenly across the surface. This allows for the coating to bond to the material seamlessly which may enhance its overall effectiveness.

There are a variety of processes that may be used to evaporate this compound onto the surface of the substrate. Some of which include, but are not limited to, electron beam sputtering, electron beam physical vapor deposition, ion assisted deposition, ion beam sputtering, or any other type of optical coating process that allows for the effective distribution of dichroitic coatings.

A possible process when using an ion beam sputtering technique is as follows:

Using a vacuum chamber and a target material (a metal oxide or any other type of material that releases electrons), a high energy ion beam is directed at the target. The ions within the beam may transfer their momentum into the target material causing atoms or molecules to sputter off. These high energy atoms/molecules that may sputter off the target material may deposit onto the substrates. Uniform, high density coatings may be achieved due to the presence of low-pressure oxygen within the coating to re-oxidize any free molecule or atom that may have become dissociated during the sputtering process.

The resulting coating may be an extremely smooth, clean surface finish that may also withstand temperature and humidity fluctuations within its environment.

Anti-Reflective Coatings: These coatings are applied to the faces of the gain medium and the photoelectric material. Having both materials coated with this anti-reflective coating may allow for the solid-state device to decrease its overall loss in photonic energy. They allow for the materials to reach the point of saturation and then allows the light to exit to prevent over saturation.

This coating is applied to the polished surface of the gain medium. There are multiple ways to adhere this coating to the exemplary embodiment. One of which includes evaporating the chemical or molecular compound evenly across the surface. This allows for the coating to bond to the material seamlessly which may enhance its overall effectiveness.

There are multiple ways to effectively bond this type of coating upon the surface of the substrate. For instance, electron beam sputtering, electron beam physical vapor deposition, ion assisted deposition, ion beam sputtering, or any other type of coating process that allows for the effective and efficient deposition of antireflective coatings upon the surface of a substrate. When using electron beam sputtering, a possible adhering process is as follows.

To initiate this process, the coating material may be heated within a high vacuum chamber until it becomes vaporized. It may be heated through electron beam bombardment when using dielectrics, or it may be heated resistively when using metals. As the coating material vaporizes, vapor may then stream away and recondense onto the surface of the substrate intended for coating.

Another process that may be utilized when using electron beam sputtering includes electron-beam physical vapor deposition. This may allow for coating at a high deposition rate without needing to heat the substrate at such high temperatures. When initiating this coating process, an electron beam may be generated and accelerated to a high kinetic energy. This high energy beam may then be directed at the evaporation material causing the electrons within the material to decrease unto a lower energy level. Interactions with the evaporation material causes kinetic energy to become converted into alternative forms of energy. Thermal energy may be one of the alternative forms of energy and may conduct heat into the evaporation material causing it to melt. The melt may then vaporize and rise to coat the surface of the substrate.

Highly Reflective Coatings: This may include a variety of different materials. The chemical or molecular compound may act as a mirror within the solid-state device. This coating's reflective properties that may either reflect all wavelengths or may selectively reflect light that is within the gain medium's peak absorption bandgap. This allows for the continuous stimulation emission within the gain medium of the solid-state device. As the initial photonic energy saturates the material and exits, excess photonic energy may then be reflected to initiate stimulated emission within the gain medium.

This coating may be located on the side furthest from the surface dichromatic layer. This allows for the ability for enhanced trapping of the gain medium's primary excitation wavelengths. With this ability to control and reflect this light, the exemplary embodiment's ability to initiate stimulated emission may be substantially improved.

This coating is applied to the polished surface of the gain medium. There are multiple ways to adhere this coating to the exemplary embodiment. Of which may include, but are not limited to, electron beam sputtering, electron beam physical vapor deposition, ion assisted deposition, ion beam sputtering, or any other type of coating process that allows for the effective and efficient deposition of highly reflective coatings upon the surface of a substrate.

A possible process when using an ion beam sputtering technique is as follows:

Using a vacuum chamber and a target material (a metal oxide or any other type of material that releases electrons), a high energy ion beam is directed at the target. The ions within the beam may transfer their momentum into the target material causing atoms or molecules to sputter off. These high energy atoms/molecules that may sputter off the target material may deposit onto the substrates. Uniform, high density coatings may be achieved due to the presence of low-pressure oxygen within the coating to re-oxidize any free molecule or atom that may have become dissociated during the sputtering process.

The resulting coating may be an extremely smooth, clean surface finish that may also withstand temperature and humidity fluctuations within its environment.

In another exemplary embodiment, a reactor may be provided.

In the embodiments, and starting with raw materials, the chemical compound aluminum oxide, Al₂O₃, is put into a crucible and synthetically grown and doped with titanium creating Ti³⁺:Al₂O₃. This new compound is known as Titanium-Sapphire. Ti-Sapphire is a unique crystal that when stimulated by a specific wavelength of light, has been known as a tunable gain medium. Currently, Ti-Sapphire is frequently used in many different laser systems due to its unique index of refraction and varying orientations. It was not until very recently that it was discovered that there was a way to both harness and sustain the gain of the Ti-Sapphire. With this revolutionary discovery, the creation of the world's first energy generation device was conceptualized and protected.

### Crystal Growth Process

To grow a crystal with a tunable gain medium, a specific type of container, such as a crucible or some other type of container that can withstand high temperatures for long periods of time, may be needed to grow the chemical compound from the raw materials into a larger crystalline structure, such as a boule. A crucible of a specific size that uses an exemplary growth method, such as the heat exchange method (HEM), the Czocharlski method, or any other type of exemplary crystal growth process may be used to grow a crystal with a tunable gain medium.

Raw materials of a specific measurement are put into the crucible and are heated to a certain degree. These raw materials include aluminum oxide Al₂O₃, or any other type of crystalline compound. During this heat exchange, the Al₂O₃ is melted down into its liquid form. A dopant such as titanium (IV) oxide (TiO₂), or any other type of metallic compound, is then introduced to the aluminum oxide and will ionically bind to form a new compound known as Ti³⁺: Al₂O₃.

Epitaxial growth may also be used to combine the dopant, such as titanium (IV) oxide (TiO₂), or any other type of metallic compound, with the melt. This process may include the inclusion of controlled gas pressure, including but not limited to controlled oxygen pressure gas. This process is performed at a specific temperature, such as 700 degrees Celsius, or any other temperature that allows for the TiO₂ to bind with the melt.

The crucible may use a specific gas, such as Argon, that creates a partial pressure causing the Ti³⁺ions to combine with the aluminum oxide creating a specific crystalline lattice structure that is intrinsic to the material. The gas may not be reactive due to its stable electron structure and will not interact with the exemplary material. A seed of a specific chemical compound is then inserted into the melt and grows the material into a boule of Ti³+: Al₂O₃. The boule is grown into a specific size and removed from the crucible. The size of the boule may be 200 mm in diameter but may be larger or smaller as well.

### Characterization of Ti-Sapphire

Once it is removed, it then can be characterized through an exemplary process, such as x-ray diffraction, spectroscopy, or any other type of exemplary characterization method. The boule may be characterized by its orientation, dopant level, and level of homogeneity.

The crystal may be oriented on a variety of different axis such as the A-axis, M-axis, C-axis, or any other axis on the crystal. The crystal may also be oriented on a random axis as well.

The dopant level may include a range from 1.5 to 5 but may also be higher or lower as well. The level of the titanium will dictate how highly doped the Ti-Sapphire is and may affect the index of refraction of the material.

The level of homogeneity may be dependent on the crystalline lattice structure of material. If the Ti³⁺:Al₂O₃ has a consistent structure and bond throughout the axis of which it has been oriented on, it may be considered more homogeneous. When the crystal has a high level of homogeneity, light may be able travel through the material with limited interruption.

### Coring of the Boule

After the boule has been characterized, it may undergo the next phase in the manufacturing process. Before the Ti-Sapphire is cut, a core may be drilled out of the boule. The core can come from the middle or any other part of the boule that is most homogenous.

This process may then result with a long rod of a specific diameter and length depending upon the size needed.

### Cutting the Rod

Once the rod has been obtained, the material can then be cut into pieces of a specific size and diameter including, but not limited to a square, rectangle, or circular shape. The core may be cut on a specific axis such as the A, M, or any other axis of the crystal.

To initiate cutting process, the Ti-Sapphire may be mounted to a part of the wire saw that enables the Ti-Sapphire to be lowered evenly onto the cutting wire. The crystal may be mounted to the wire saw using a specific chemical compound that may hold the crystal in place as it is cut.

The cutting wire may be made of a variety of materials impregnated with diamond, or any other type of molecule, or compound, that may be durable enough to cut through Ti-Sapphire.

The machine may emit a particular aqueous chemical substance that may wash away excess debris and may also keep the crystal cool as the crystal is cut.

As the wire saw rocks, the wire may cut through a particular axis of the Ti-Sapphire. The wire may cut the sapphire straight down the crystal or it may cut the crystal at a specific curvature depending upon which cut creates a gain that is most efficiently harnessed.

### Cleaning of the Ti-Sapphire

This process may continue until the wire has cut through the crystal cleanly. The Ti-Sapphire may be removed from the wire-saw and then rinsed in a bath formed of specific chemicals that may have the ability to rinse the crystal and remove any extra particles.

After the Ti-Sapphire has been rinsed, it may then be placed in a tub of boiling water. This allows for the crystal to be removed from the adhesive. The adhesive may be formed of specific chemical compounds that may allow the crystal to remain attached to the wire saw during the cutting process.

At this point, the cut Ti-Sapphire is known as a ‘reactor’; the part of the ‘power core’ that allows for the spontaneous creation and emission of new photons of the device.

### Polishing the blanks

The reaper is then polished and fabricated. During this process, the reactor's edges may be cut straight, beveled, or in any other way that allows for the reaper to harness more photonic energy. The reactor is then cut at specific angles at each of the sides. These angles can be cut at 90°, 60.4° also known as a Brewster angle, or at any other angle that prevents the escape of light from the material.

If when using a Brewster cut, the angle may be on the A plane, the M plane, both, and/or any other plane of the reaper. This specific angling may allow for photons to bounce off the angle and exit the material at a different plane, such as the C, or any other plane of the reaper.

Once the reactor has been angled, it may undergo the next stage of polishing. The polishing can include several steps that lead to a completely smooth and glossy reaper. These steps may include, but are not limited to, chemical mechanical polishing, or any other type of crystal polishing.

During this process, the reactor is held with pads of a specific material that does not scratch the surface of the reactor and may remove any roughness of the material to produces a glossy finish. The pads can be made of polyurethane, politex, or any other type of material that effectively polishes the reactor. The pads rotate at a specific speed and rate, including but not limited to 100 rotations per minute, or any other specific number of rotations per minute that enable the material to become effectively polished.

This process also may include a type of liquid that continuously washes away any fragments and keeps the material cool. The slurry may be silica based, aluminum based, or any other type of chemical compound that keeps the material clean as the pads polish the material.

Once the reactor has become effectively polished, it may be ready for the next stage in the manufacturing process.

### Coating the Ti-Sapphire

The reactor may be coated with a variety of exemplary coatings that may regulate the amount of light that is both harnessed and emitted by the reactor. Coatings may be on just one side, or on every side of the reactor, depending upon which design works most efficiently in modulating photonic energy retainment and emission.

Antireflective (AR) coatings may be placed on the sides, ends, or faces of the reactor depending upon the orientation of the material and which side is meant to easily transmit photonic energy. This AR coating may be made of specific chemical or molecular compound that effectively allows for wavelengths within the absorption spectrum of the reactor to enter the substrate with minimal reflection losses. This may be completed by the AR coating's ability to effectively produce two reflections that interfere destructively with one another allowing for seamless transmission of photonic energy within the bandgap that the AR is tuned specifically. There may be one or more layers of AR coatings on any side of the reactor.

Antireflective coatings may be deposited onto the substrate using a variety of different coating deposition methods. Some include, but are not limited to electron beam sputtering, electron beam physical vapor deposition, ion assisted deposition, ion beam sputtering, or any other type of coating process that allows for the effective and efficient deposition of antireflective coatings upon the surface of a substrate. When using electron beam sputtering, a possible adhering process is as follows.

To initiate this process, the coating material may be heated within a high vacuum chamber until it becomes vaporized. It may be heated through electron beam bombardment when using dielectrics, or it may be heated resistively when using metals. As the coating material vaporizes, vapor may then stream away and recondense onto the surface of the substrate intended for coating.

Another process that may be utilized when using electron beam sputtering includes electron-beam physical vapor deposition. This may allow for coating at a high deposition rate without needing to heat the substrate at such high temperatures. When initiating this coating process, an electron beam may be generated and accelerated to a high kinetic energy. This high energy beam may then be directed at the evaporation material causing the electrons within the material to decrease unto a lower energy level. Interactions with the evaporation material causes kinetic energy to become converted into alternative forms of energy. Thermal energy may be one of the alternative forms of energy and may conduct heat into the evaporation material causing it to melt. The melt may then vaporize and rise to coat the surface of the substrate.

Highly reflective (HR) coatings may be placed on the sides, ends, or faces of the reactor depending upon the orientation of the material and which side is meant to reflect the photonic energy pumped into the material. This HR coating may be made of a specific chemical or molecular compound that effectively reflect the specific wavelength of photonic energy pumped into the reactor. These compounds may include but are not limited to an aluminum or chromium compound. This may be completed by the HR coating's multilayer system. One layer may be included of a chemical or molecular compound that has a high index of refraction, such as zinc sulfide or any other type of molecular or chemical compound that has a high index of refraction and is specific to the wavelength of light emitted by the pump source of the reactor. The next layer may include a chemical or molecular compound that has a low index of refraction such as magnesium fluoride or silicon dioxide or any other chemical or molecular compound that has a low index of refraction and is specific to the wavelength of light emitted by the pump source of the reactor. A type of HR coating that may be used is a dielectric mirror. This dielectric coating that can be manipulated with the variation of in thickness of dielectric layers that is specifically designed to reflect a specific wavelength of light. This type of coating is often used in the Ti-Sapphire laser system.

There are multiple ways to adhere this coating to the exemplary embodiment. Of which may include, but are not limited to, electron beam sputtering, electron beam physical vapor deposition, ion assisted deposition, ion beam sputtering, or any other type of coating process that allows for the effective and efficient deposition of highly reflective coatings upon the surface of a substrate.

A possible process when using an ion beam sputtering technique is as follows:

Using a vacuum chamber and a target material (a metal oxide or any other type of material that releases electrons), a high energy ion beam is directed at the target. The ions within the beam may transfer their momentum into the target material causing atoms or molecules to sputter off. These high energy atoms/molecules that may sputter off the target material may deposit onto the substrates. Uniform, high density coatings may be achieved due to the presence of low-pressure oxygen within the coating to re-oxidize any free molecule or atom that may have become dissociated during the sputtering process.

The resulting coating may be an extremely smooth, clean surface finish that may also withstand temperature and humidity fluctuations within its environment.

Dichromatic coatings may also be placed on the sides, ends, or faces of the reactor depending upon the orientation of the material and which side is meant to allow the newly created photonic energy emitted by the reactor to exit the material. This coating may include a variety of layers of differing chemical or molecular compounds that may allow for a specific wavelength of light to exit the material, while simultaneously retaining any other wavelength of light inside the reactor. This allows for reactor to regulate which wavelengths of light are emitted and which wavelengths of light are retained within the material.

There are multiple ways to deposit this coating to the exemplary embodiment. One of which includes evaporating the chemical or molecular compound evenly across the surface. This allows for the coating to bond to the material seamlessly which may enhance its overall effectiveness.

There are a variety of processes that may be used to evaporate this compound onto the surface of the substrate. Some of which include, but are not limited to, electron beam sputtering, electron beam physical vapor deposition, ion assisted deposition, ion beam sputtering, or any other type of optical coating process that allows for the effective distribution of dichroitic coatings.

A possible process when using an ion beam sputtering technique is as follows:

Using a vacuum chamber and a target material (a metal oxide or any other type of material that releases electrons), a high energy ion beam is directed at the target. The ions within the beam may transfer their momentum into the target material causing atoms or molecules to sputter off. These high energy atoms/molecules that may sputter off the target material may deposit onto the substrates. Uniform, high density coatings may be achieved due to the presence of low-pressure oxygen within the coating to re-oxidize any free molecule or atom that may have become dissociated during the sputtering process.

The resulting coating may be an extremely smooth, clean surface finish that may also withstand temperature and humidity fluctuations within its environment.

Once the reactor has been properly coated to meet the specifications that may be needed to modulate the specific wavelengths of light reflected within the material, the specific wavelengths of light that are blocked from exiting the material, and the wavelengths of light that are able to emit from the material, the material may be ready to move on to the next stage of manufacturing.

### Implementation of Photon Blasters

A specific kind of light emitting chemical or molecular compound is then adhered to the sides, ends, or face of the reactor. These light emitting chemicals may include light emitting diodes, or any other type of chemical or molecular compounds that emit specific wavelengths of light that are highly transmittable through the reactor. These light emitting materials are further referred to as ‘photon-blasters’.

These photon-blasters may include a specific chemical or molecular compound that illuminates a specific wavelength of light that is in the peak absorption range of the reactor. The chemical or molecular compound may include indium gallium nitride (InGaN), aluminum gallium indium phosphide (AlGnInP), aluminum gallium arsenide (AlGaAs), or any other type of chemical or molecular compound that emits a specific wavelength of light that is in the peak absorption range of the reactor.

These photon-blasters may emit a specific wavelength of light that stimulates a quantum photonic phenomenon inside the reactor. This quantum photonic phenomenon includes, but is not limited to, the spontaneous emission of a new photon for every photon pumped into the reactor when the wavelength is in the peak absorption spectrum for the reactor. This wavelength may include, but is not limited to 532 nm, or any other wavelength that is easily absorbed and re-mitted as an alternative wavelength by the reactor.

The photon-blaster may also have a coating over the surface of the material where photons are emitted. This coating may amplify the light stimulated by the photon-blaster. This coating includes Ti³⁺:Al₂O₃, or any other type of chemical or molecular compound that readily amplifies the photonic energy stimulated by the photon blaster.

These photon-blasters may be adhered to the reactor in relation to the coatings and orientation of reactor. These coatings include the antireflective, highly reflective, and/or dichromatic coatings, or any other type of coating on the reactor that alters the index of refraction of the light emitted by the photon blaster. The orientation of the reactor may also dictate where the photon-blaster is placed. The photon-blaster may be adhered to the A-plane, the M-plane, or any other plane that has a specific index of refraction that allows for the photonic energy to easily pass through the reactor and stimulate a specific reaction. Depending upon location of the coatings and the orientation of the material, the photon-blaster will be adhered to the reactor at a specific incidence angle and location that allows for the most photonic energy to saturate the material. When the reactor is saturated, the creation of newly emitted photons is stimulated for every photon pumped into the material.

A specific number of photon-blasters are placed in a specific location on the reactor that allows for the material to completely saturate. This number may include one or more photon blasters deposited on whatever plane or planes that allow for the photonic energy to easily pass through and stimulate the reactor.

The photon-blasters may require a specific amount of power to accurately emit the photonic energy necessary to saturate the reactor. These photon reactors may need an initial jump start from an external photovoltaic that will convert photonic energy from the sun into electrical energy to power the photon-blaster. After this initial jump-start, the creation of new photonic energy resulting from the quantum photonic phenomena within the reactor may be enough to supplement the power supplied the photon-blasters.

The photon-blasters may either stimulate photonic energy in pulses or at a continuous constant wave of photonic energy depending upon which method results in greater amount of photonic energy emitted by the reactor. If constant wave were to create the greatest amount of photonic energy emitted by the reactor, the photon-blasters may breathe on and off as thermal conditions rise within the material. Therefore, if one photon-blaster began to produce a high amount of thermal energy and was at risk for burning out, the next photon-blaster may breathe on at the same rate the other would breathe off. This rate of breathing on and off as thermal conditions become less than ideal, may allow for a constant wave of photonic energy to consistently stimulate the reactor. This process may allow for the potential for continuous photonic energy generation and emission from the reactor.

### Depositing the Reapers

The next part of the exemplary embodiment may include the chemical or molecular compound that may be deposited on the specific side of the reactor that emits photonic energy. This side may include the face that includes the dichromatic coating, or any other type of exemplary coating, that allows for specific wavelengths of light to exit the reactor.

This component with photoreactive capabilities may be known as the ‘reaper’. The reaper includes a specific chemical or molecular compound that is photoreactive to the specific wavelengths of light emitted by the reactor. The reaper may be a photovoltaic, or any other type of molecular or chemical compound that has a high absorption efficiency for wavelengths of light that are emitted by the reactor.

The reaper may contain a specific chemical or molecular compound, such as gallium arsenide, crystalline silicon, or any other type of chemical or molecular compound that has a high absorption efficiency for light emitted by the reactor.

The reaper may absorb the photonic energy emitted by the reactor and may convert this energy into electrical energy. This happens through an exemplary process, such as the photovoltaic effect, or any other type of process that involves the transformation of photonic energy into electrical energy, such as a current, voltage, or resistance.

The reaper may absorb photonic energy with one single layer, may also be known as single junction, or through the composition of multiple differing physical configurations, may also be known as multi-junction. The number of layers may correspond to the peak effectiveness of the reapers ability to absorb photonic energy and convert it into electrical energy.

The reaper may also have specific material that has high-reflective capabilities to prevent the loss of photonic energy and allows it to reflect into the reaper. This material may be deposited evenly on the back of the reaper, or another location on the reaper that enables the material to reflect the light emitted by the reactor back into the reaper. This material may be made of a specific chemical or molecular compound such as copper or gold, or any other type of chemical or molecular compound that highly reflective for the specific wavelengths that are emitted by the reactor.

The reaper may also have positive and negative terminals that allow for the electrical energy to travel from the reaper onto a material connected to the reaper. This substance may be a circuit board, or any other type of material that can retain and transfer this electrical energy submitted by the reaper.

### Integration into the Circuitry

The reactor may then be put onto a circuit board once the coatings, photon blasters, and reapers have all been individually added to the reactor in a way that allows for the greatest amount of photonic energy to be emitted by the reactor and harnessed by the reaper. The reaper then converts the photonic energy into electrical energy.

The electrical energy from the reaper may be transmitted into the circuit board, or another type of exemplary material that can store and emit electrical energy when connected to the reaper.

The circuit board, or another type of exemplary material that can interpret electrical energy, may either store excess electrical energy transmitted by the reaper or may transmit this electrical energy into a convertible form of current that is readable by an electronic device connected to the circuitry.

The number of reactors may differ depending upon what the circuitry is programed to transmit electrical current into. If the device the circuitry is supplying power to requires a substantial amount of power, such as a car, the number of reactors may increase to compensate for the increase in power demands.

It should be understood that all of the embodiments and examples described herein are merely exemplary and should be considered as non-limiting.

What is claimed is:

1. A device comprising:
one or more blasters configured to generate photonic energy based on an electrical current;
one or more power cores configured to receive the photonic energy emitted from the one or more blasters; and
one or more reapers configured to receive the photonic energy from the one or more power cores and convert the photonic energy into electrical energy,
wherein the one or more power cores comprise a crystalline lattice structure selected from the group consisting of: Ti³⁺: Al₂O₃, Nd:YAG, Nd:YVO₄, Cs:YAG, Er;YAG, and Ce:YAG.

2. The device of claim 1, wherein the one or more blasters are configured to emit the photonic energy as a timed pulse.

3. The device of claim 1, wherein the one or more blasters are configured to emit the photonic energy as a constant wave.

4. The device of claim 1, wherein the one or more power cores have a shape selected from the group consisting of: spherical, rectangular, and triangular.

5. The device of claim 1, wherein the one or more power cores comprise one or more absorption faces, and
wherein at least one absorption face of the one or more power cores is oriented at an incident angle that facilitates entry of photonic energy comprising wavelengths within an absorption bandgap of the one or more power cores.

6. The device of claim 5, wherein the incident angle of the at least one absorption face comprises a Brewster angle.

7. The device of claim 1, wherein the one or more blasters comprise a semiconductor selected from the group consisting of: GaAs, GaAsP, InGaN, AlGaInP, AlGaAs, and GaP.

8. The device of claim 1, wherein the one or more reapers comprise a crystalline photoelectric material selected from the group consisting of: GaAs, InGaN, GaInP, monocrystalline silicon, polycrystalline silicon, SiN, and CdTe.

9. The device of claim 1, wherein the one or more power cores comprise a reflective coating configured to reflect wavelengths of photonic energy within an absorption bandgap of the one or more power cores.

10. The device of claim 9, wherein the reflective coating comprises a high index of refraction material and a low index of refraction material,
wherein the high index of refraction material is selected from the group consisting of: zinc sulfide and titanium dioxide, and
wherein the low index of refraction material is selected from the group consisting of:
magnesium fluoride and silicon dioxide.

11. The device of claim 1, wherein the one or more reapers have a first face and a second face,
wherein the first face is oriented towards an emission face of the one or more power cores that facilitates entry of photonic energy emitted from the one or more power cores, and
wherein the second face comprises a reflective coating to reduce photonic energy loss.

12. The device of claim 1, wherein at least one of an emission face of the one or more power cores and an absorption face of the one or more reapers comprise an antireflective coating to reduce photonic energy loss,
wherein the antireflective coating comprises a plurality of optical coatings, each optical coating having a refractive index different from at least one other optical coating.

13. The device of claim 1, wherein at least one of an emission face of the one or more blasters and an absorption face of the reapers comprise an index matching coating,
wherein the index matching coating comprises a plurality of optical coatings, each optical coating having a refractive index different from at least one other optical coating.

14. The device of claim 4, wherein the one or more power cores comprise a dichromatic coating configured to transmit wavelengths of photonic energy within an absorption bandgap of the one or more power cores.

15. The device of claim 14, wherein the dichromatic coating is a bandpass filter.

16. The device of claim 1, wherein an emission bandgap of the one or more blasters matches an absorption bandgap of the one or more power cores, and
wherein an emission bandgap of the one or more power cores matches an absorption bandgap of the one or more reapers.

17. A device comprising:
one or more blasters configured to generate photonic energy based on an electrical current;
one or more power cores configured to receive the photonic energy emitted from the one or more blasters; and
one or more reapers configured to receive the photonic energy from the one or more power cores and convert the photonic energy into electrical energy,
wherein at least one of the one or more power cores comprises a first face and a second face,
the first face comprises a dichromatic coating configured to transmit wavelengths of photonic energy within an absorption bandgap of the at least one of the one or more power cores, and
the second face comprises a reflective coating configured to reflect the wavelengths of photonic energy within the absorption bandgap of the at least one of the one or more power cores.

18. The device of claim 17, wherein the dichromatic coating and the reflective coating are deposited by a process selected from the group consisting of: physical vapor deposition, ion assisted deposition, ion beam sputtering, and electron beam sputtering.

19. A device comprising:
one or more blasters configured to generate photonic energy based on an electrical current;
one or more power cores configured to receive the photonic energy emitted from the one or more blasters; and
one or more reapers configured to receive the photonic energy from the one or more power cores and convert the photonic energy into electrical energy,
wherein at least a portion of the electrical energy converted by the one or more reapers is configured to provide the electrical current to the one or more blasters to generate the photonic energy.

20. The device of claim 19, wherein the device is configured to operate without an external power source after an initial power source is applied.
